(19) United States
(12) Patent Application Publication
(10) Pub. No.: US 2006/0249736 A1
(43) Pub. Date: Nov. 9, 2006

(54) Nitride semiconductor light emitting device and method of manufacturing the same

(75) Inventors: Jae Hoon Lee, Suwon (KR); Hyung Ky Back, Suwon (KR); Moon Heon Kong, Suwon (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/414,371

(22) Filed: May 1, 2006

(30) Foreign Application Priority Data
May 3, 2005 (KR) 10-2005-0037056

(51) Int. Cl. H01L 33/00

(52) U.S. Cl. 257/79

(57) ABSTRACT

The present invention relates to a nitride semiconductor light emitting device. The nitride semiconductor light emitting device includes an n-type electrode; an n-type nitride semiconductor layer that is formed to come in contact with the n-type electrode; an active layer that is formed on the n-type nitride semiconductor layer; a p-type nitride semiconductor layer that is formed on the active layer; an undoped GaN layer that is formed on the p-type nitride semiconductor layer; an AlGaN layer that is formed on the undoped GaN layer so as to provide a two-dimensional electron gas layer to the interface with the undoped GaN layer; a reflecting layer that is formed on the AlGaN layer; a barrier that is formed so as to surround the reflecting layer; and a p-type electrode that is formed on the barrier.

### CROSS-REFERENCE TO RELATED APPLICATIONS

The application claims the benefit of Korea Patent Application No. 2005-0037056 filed with the Korea Industrial Property Office on May 3, 2005, the disclosure of which is incorporated herein by reference.

### BACKGROUND OF THE INVENTION

1. Field of the Invention

The present invention relates to a nitride semiconductor light emitting device and a method of manufacturing the same, and more specifically, to a nitride semiconductor light emitting device which can reduce an operational voltage and enhance a current-spreading effect, while minimizing a current leakage due to a reflecting material such as silver, and a method of manufacturing the same.

2. Description of the Related Art

In general, a nitride semiconductor is such a material that has a relatively high energy band gap (in the case of GaN semiconductor, about 3.4 eV), and is positively adopted in a light emitting device for generating green or blue short-wavelength light. As such a nitride semiconductor, a material having a composition of AlₓIn_{y}Ga_{(1-x-y)}N (herein, 0≦x≦1, 0≦y≦1, and 0≦x+y≦1) is widely used.

However, since such a nitride semiconductor has a relatively large energy band-gap, it is difficult to form the ohmic contact with an electrode. Particularly, since a p-type nitride semiconductor layer has a larger energy band-gap, the contact resistance on the contact portion with a p-type electrode increases. Such an increase causes an operational voltage of the device to increase, thereby increasing the heating value. Further, in the p-type nitride semiconductor layer, a larger increase in resistance occurs due to an ICP-RIE process which is one etching process for forming a nitride semiconductor light emitting device.

Therefore, in the nitride semiconductor light emitting device, it is required that the ohmic contact should be changed for the better when the p-type electrode is formed.

Recently, in order to increase the brightness of the nitride semiconductor light emitting device, metal such as silver (Ag) which is frequently used as a reflecting layer material is adopted as a rear surface reflecting layer. Then, the light which is emitted to the opposite surface to the front surface is reflected to the front side through the rear surface reflecting layer, and the light which is reduced due to low transmittance of a conventional p-type electrode is saved, thereby increasing the light extraction efficiency.

However, the reflecting material such as silver (Ag) composing the rear surface reflecting layer is easily diffused. Such diffusion causes leakage current to be generated, thereby reducing the yield and reliability of the light emitting device.

Therefore, in the nitride semiconductor light emitting device, it is required that the reflecting material composing the rear surface reflecting layer should be prevented from being diffused.

Such a nitride semiconductor light emitting device is roughly divided into a flip chip light emitting diode and a vertically-structured light emitting diode. Hereinafter, the problems of the nitride semiconductor light emitting device according to the related art will be described in detail with reference to FIGS. 1 and 2, with a flip chip light emitting diode of the nitride semiconductor light emitting device being exemplified.

FIG. 1 is a cross-sectional view illustrating the structure of the nitride semiconductor light emitting device according to the related art, and FIG. 2 is an enlarged photograph showing a portion A of FIG. 1.

As shown in FIG. 1, the nitride semiconductor light emitting device 100 according to the related art includes an n-type nitride semiconductor layer 120, a GaN/InGaN active layer 130 having a multi-quantum well structure, and a p-type nitride semiconductor layer 140, which are sequentially formed on a sapphire substrate 110. Portions of the p-type nitride semiconductor layer 140 and the GaN/InGaN active layer 130 are removed by mesa-etching, so that a portion of the upper surface of the n-type nitride semiconductor layer 120 is exposed.

On the n-type nitride semiconductor layer 120, an n-type electrode 180 is formed. On the p-type nitride semiconductor layer 140, a p-type electrode 170 composed of Ni/Au is formed.

Such a p-type nitride semiconductor layer 140 has a larger energy band gap. Therefore, if the p-type nitride semiconductor layer 140 comes in contact with the p-type electrode 170, the contact resistance increases, thereby increasing the operational voltage of the device. As a result, the heating value increases.

Between the p-type nitride semiconductor layer 140 and the p-type electrode 170, a rear surface reflecting layer 150 is positioned so as to increase the brightness of the nitride semiconductor light emitting device. The rear surface reflecting layer 150 is blocked by a barrier 160 which is positioned thereon and is formed of a metallic material such as Cr/Ni or TiW.

As shown in FIG. 2, in the nitride semiconductor light emitting device according to the related art, thickness deviation occurs in the end portion of the rear surface reflecting layer 150 due to a lift-off process, when the rear surface reflecting layer 150 is formed by using such a material as silver (Ag), that is, when the lift-off process for forming the rear surface reflecting layer is performed.

If the thickness deviation occurs in the end portion of the rear surface reflecting layer 150 as described above, the reflecting material such as silver composing the rear surface reflecting layer 150 is diffused through the barrier 160 adjacent to the rear surface reflecting layer 150 in which the thickness deviation occurred, which is a cause to increase the leakage current of the light emitting device.

Further, the barrier 160 completely covers the rear surface reflecting layer 150 and comes in contact with the p-type nitride semiconductor layer 140 so as to prevent the reflecting material from being diffused outside. However, a defect in the contact between the metallic material such as Cr/Ni or TiW composing the barrier 160 and the semiconductor composing the p-type nitride semiconductor layer 140 causes the leakage current of the light emitting device to further increase. As a result, the characteristic and reliability of the nitride semiconductor light emitting device are deteriorated, and the yield is also reduced.

### SUMMARY OF THE INVENTION

An advantage of the present invention is that it provides a nitride semiconductor light emitting device which can reduce an operational voltage and can enhance a current-spreading effect, while minimizing a leakage current due to a reflecting material such as silver.

Another advantage of the invention is that it provides a method of manufacturing the nitride semiconductor light emitting device.

Additional aspects and advantages of the present general inventive concept will be set forth in part in the description which follows and, in part, will be obvious from the description, or may be learned by practice of the general inventive concept.

According to an aspect of the invention, a nitride semiconductor light emitting device includes an n-type electrode; an n-type nitride semiconductor layer that is formed to come in contact with the n-type electrode; an active layer that is formed on the n-type nitride semiconductor layer; a p-type nitride semiconductor layer that is formed on the active layer; an undoped GaN layer that is formed on the p-type nitride semiconductor layer; an AlGaN layer that is formed on the undoped GaN layer so as to provide a two-dimensional electron gas layer to the interface with the undoped GaN layer; a reflecting layer that is formed on the AlGaN layer; a barrier that is formed so as to surround the reflecting layer; and a p-type electrode that is formed on the barrier.

Preferably, the barrier is formed on the AlGaN layer, and is composed of a first barrier which has a larger thickness than the reflecting layer and a second barrier which is formed on the reflecting layer while coming in contact with the side wall of the first barrier. More preferably, the first barrier is formed of any one selected from a group composed of undoped GaN, SiO₂, and SiNₓ, and the second barrier is formed of Cr/Ni or TiW. Such a construction enhances the adherence between the AlGaN layer and the first barrier formed on the AlGaN layer, thereby preventing the reflecting material of the reflecting layer from being diffused due to an adhesion defect.

Preferably, the undoped GaN layer has a thickness of 50 to 500 Å, and the Al content of the AlGaN layer is in the range of 10 to 50% in consideration of the crystallinity. In this case, the AlGaN layer has a thickness of 50 to 500 Å in order to form the two-dimensional electron gas layer.

Preferably, the AlGaN layer is an undoped AlGaN layer or an AlGaN layer which is doped with an n-type impurity such as Si.

The AlGaN layer contains silicon or oxygen as an impurity. The silicon can act as a donor such as Si, and the oxygen can be contained through native oxidation. However, it is preferable that sufficient oxygen content should be secured by purposely annealing the AlGaN layer in an oxygen atmosphere.

Preferably, a contact layer is included between the AlGaN layer and the reflecting layer.

Accordingly, it is possible to implement the vertically-structured nitride semiconductor light emitting device, in which the n-type electrode is formed on the rear surface of the n-type nitride semiconductor layer on which the active layer is formed. Further, it is possible to implement the nitride semiconductor light emitting device having a flip chip structure, in which the n-type electrode is formed on the n-type nitride semiconductor layer so as to be spaced at a predetermined distance from the active layer and which includes the active layer and the substrate formed on the rear surface of the n-type nitride semiconductor layer on which the n-type electrode is formed.

According to another aspect of the invention, a method of manufacturing a nitride semiconductor light emitting device includes forming an n-type nitride semiconductor layer on a substrate; forming an active layer on the n-type nitride semiconductor layer; forming a p-type nitride semiconductor layer on the active layer; forming an undoped GaN layer on the p-type nitride semiconductor layer; forming an AlGaN layer on the undoped GaN layer so that a two-dimensional electron gas layer is formed in the junction interface with the undoped GaN layer; forming a reflecting layer and a barrier on the AlGaN layer, the barrier surrounding the reflecting layer; forming a p-type electrode on the barrier; and forming an n-type electrode which comes in contact with the n-type nitride semiconductor layer.

Preferably, forming the reflecting layer and the barrier on the AlGaN layer, the barrier surrounding the reflecting layer, further includes patterning a first barrier defining the reflecting layer forming region on the AlGaN layer; forming the reflecting layer in the reflecting layer forming region on the AlGaN layer so that the reflecting layer has a smaller height than the first barrier; and forming a second barrier on the first barrier and the reflecting layer.

Preferably, patterning the first barrier includes growing the undoped GaN layer on the AlGaN layer so that the undoped GaN layer has a predetermined thickness; and selectively etching the grown undoped GaN layer so that the reflecting layer forming region is defined. Alternately, patterning the first barrier includes forming a silicon-based insulating film on the AlGaN layer so that the insulating film has a predetermined thickness; and selectively etching the silicon-based insulating film so that the reflecting layer forming region is formed.

As such, in the present invention, the two-dimensional electron gas (2 DEG) layer structure is adopted on the p-type nitride semiconductor layer in order to reduce the contact resistance of the p-type nitride semiconductor layer. Particularly, since the 2 DEG structure has high electron mobility, the current-spreading effect can be improved.

Further, the side wall barrier and the upper surface barrier are provided so as to completely surround and block the reflecting layer, in order to prevent the diffusion of the reflecting layer. Particularly, since the side wall barrier is formed of an undoped GaN or silicon-based nitride which is strongly adhesive with the lower AlGaN layer, the diffusion of the reflecting layer due to a contact defect can be prevented.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view illustrating the structure of a nitride semiconductor light emitting device according to the related art;

FIG. 2 is an expanded photograph showing a portion A of FIG. 1;

FIG. 3 is a cross-sectional view illustrating the structure of a nitride semiconductor light emitting device according to a first embodiment of the present invention;

FIG. 4 is an energy band diagram showing a heterojunction band structure adopted in the nitride semiconductor light emitting device shown in FIG. 3;

FIGS. 5A to 5F are cross-sectional views for sequentially showing a method of manufacturing the nitride semiconductor light emitting device according to the first embodiment of the invention;

FIG. 6 is a cross-sectional view illustrating the structure of a nitride semiconductor light emitting device according to a second embodiment of the invention; and

FIGS. 7A to 7C are cross-sectional views for sequentially showing a method of manufacturing the nitride semiconductor light emitting device according to the second embodiment of the invention.

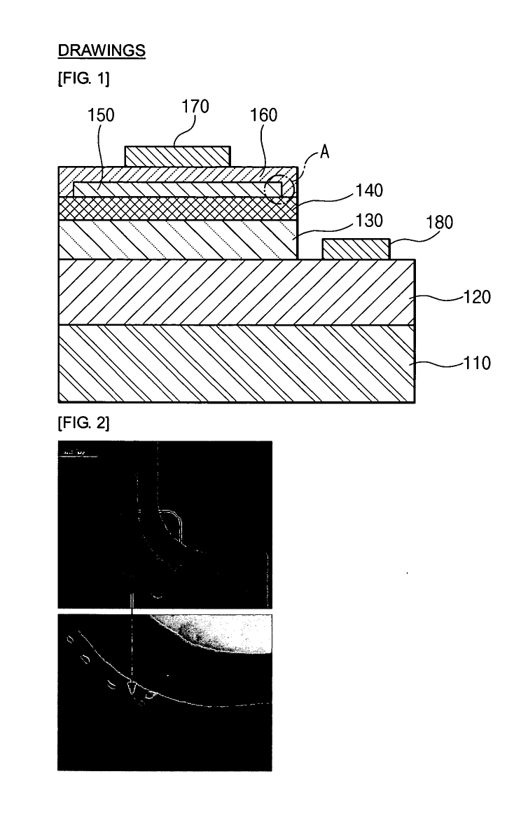

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

Hereinafter, preferred embodiments of the present invention will be described in detail with reference to the accompanying drawings so that the present invention can be easily embodied by a person with an ordinary skill in the art.

In the drawings, the thickness of each layer is enlarged in order to clearly illustrate various layers and regions.

Hereinafter, a nitride semiconductor light emitting device according to an embodiment of the present invention and a method of manufacturing the same will be described in detail with reference to the accompanying drawings.

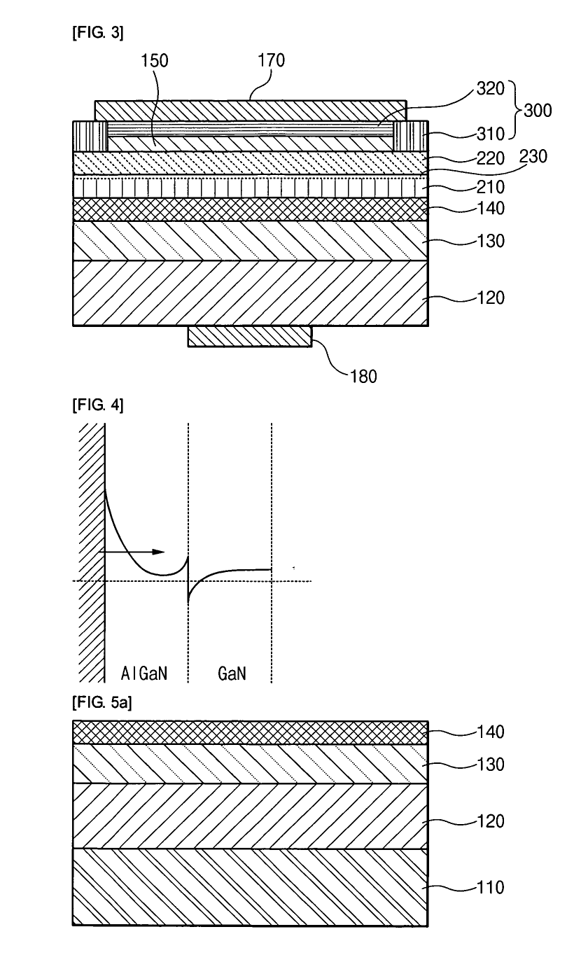

First, a nitride semiconductor light emitting device according to a first embodiment of the invention will be described in detail with reference to FIGS. 3 and 4.

FIG. 3 is a cross-sectional view illustrating the structure of the nitride semiconductor light emitting device according to the first embodiment of the invention, and FIG. 4 is an energy band diagram showing a heterojunction band structure which is adopted in the nitride semiconductor light emitting device shown in FIG. 3.

As shown in FIG. 3, an n-type nitride semiconductor layer 120, an active layer 130, and a p-type nitride semiconductor layer 140 are sequentially laminated on an n-type electrode 180.

The n-type or p-type nitride semiconductor layers 120 or 140 can be formed of a GaN layer or GaN/AlGaN layer which is doped with a conductive impurity. The active layer 130 can have a multi-quantum well structure which is composed of an InGaN/GaN layer.

On the p-type nitride semiconductor layer 140, a two-dimensional electron gas (2 DEG) layer 230 is formed, in which an undoped GaN layer 210 and an AlGaN layer 220 are sequentially laminated as a heterogeneous substance. The two-dimensional electron gas layer 230 serves to reduce the contact resistance of the p-type nitride semiconductor layer and to improve a current-spreading effect.

Now, the structure of the two-dimensional electron gas (2 DEG) layer 230 in which the undoped GaN layer 210 and the AlGaN layer 220 are sequentially laminated as a heterogeneous substance will be described in detail with reference to FIG. 4.

Referring to FIG. 4, the undoped GaN layer 210 is provided with the two-dimensional electron gas layer 230 which is formed at the interface with the AlGaN layer 220 by the energy band discontinuity with the AlGaN layer 220. Therefore, when a voltage is applied, tunneling occurs in the n⁺-p⁺ junction through the two-dimensional electron gas layer 230, thereby reducing the contact resistance.

In the two-dimensional electron gas layer 230, high carrier mobility (about 1500 cm²/Vs) is guaranteed. Therefore, a current-spreading effect can be significantly improved.

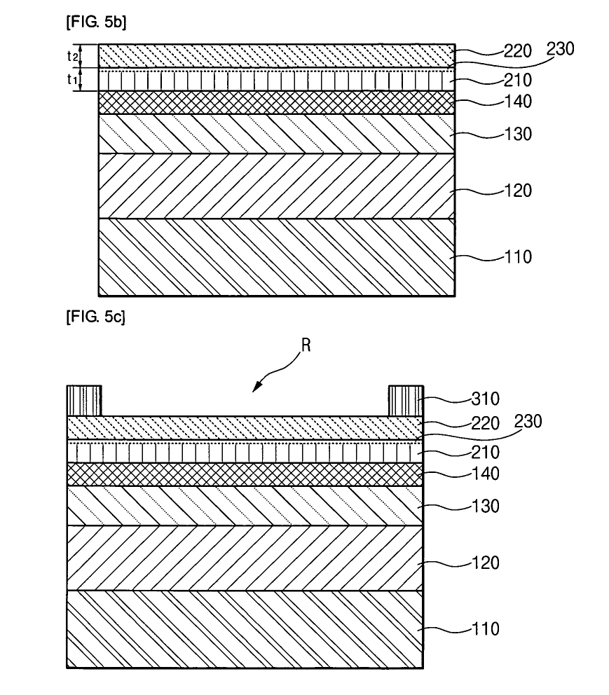

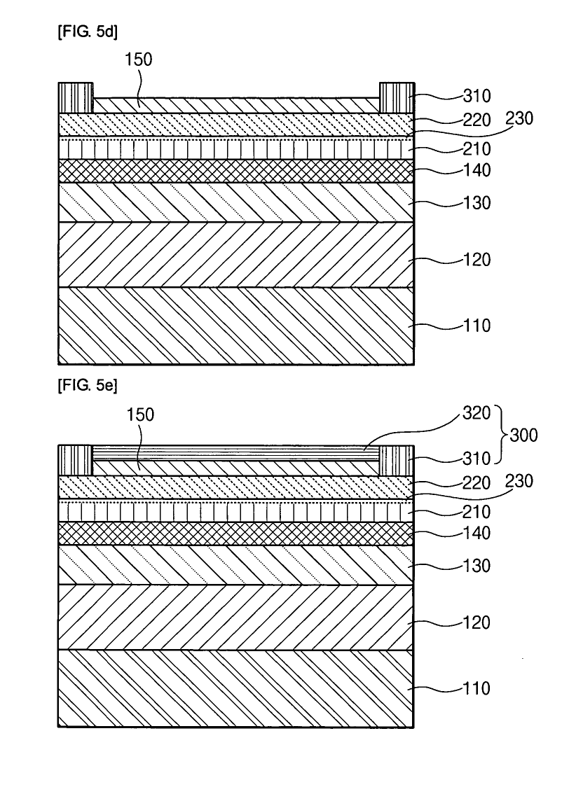

A condition where such a two-dimensional electron gas layer 230 is preferably formed can be explained by the respective thicknesses t1 and t2 (refer to FIG. 5B) of the undoped GaN layer and the AlGaN layer 220 and the Al content of the AlGaN layer 220.

More specifically, the thickness t1 of the undoped GaN layer 210 is preferably in the range of 50 to 500 Å in consideration of the tunneling effect of the two-dimensional electron gas layer 230. In the present embodiment, the undoped GaN layer 210 is formed to have a thickness of 80 to 200 Å.

The thickness t2 of the AlGaN layer 220 can be changed according to the Al content. However, when the Al content is high, the crystallinity can be reduced. Therefore, the Al content of the AlGaN layer 220 is preferably limited to 10 to 50%. In such a content condition, the thickness of the AlGaN layer 220 is preferably in the range of 50 to 500 Å. In the present embodiment, the AlGaN layer 220 is formed to have a thickness of 50 to 350 Å.

As the AlGaN layer 220 for forming the two-dimensional electron gas layer 230, an undoped AlGaN layer as well as the n-type AlGaN layer can be adopted. At this time, when the n-type AlGaN layer is formed, Si can be used as an n-type impurity.

In the two-dimensional electron gas layer 230 which is formed by the GaN/AlGaN layer structure, relatively high sheet carrier density (about 10¹³/cm²) is guaranteed. However, oxygen can be additionally adopted as an impurity in order to obtain higher carrier density. Since the oxygen introduced into the AlGaN layer 220 acts as a donor such as Si, doping concentration is increased and Fermi level is fixed, thereby increasing the tunneling. Therefore, carriers supplied to the two-dimensional electron gas layer 230 are increased to further increase the carrier density, which makes it possible to further improve the contact resistance.

Introducing the oxygen acting as a donor into the AlGaN layer 220 can be performed through native oxidation in an electrode forming process or the like without an additional process, because the AlGaN material is highly reactive with oxygen. However, when sufficient oxygen needs to be introduced, for example, when an undoped AlGaN layer is formed, a separate oxygen-introducing process is preferably performed on purpose.

In the present invention as described above, the GaN/AlGaN heterojunction structure is provided on the p-type nitride semiconductor layer 140, so that the contact resistance can be significantly improved through the tunneling effect using the two-dimensional electron gas layer 230. Further, such a method allows the contact resistance and current injection efficiency to be improved, while a transparent electrode such as Ni/Au having low transmittance is not added or the impurity concentration of the p-type nitride semiconductor layer 140 is not increased excessively.

In addition, on the AlGaN layer 220 composing the two-dimensional electron gas layer 230, a reflecting layer 150 formed of a reflecting material such as Ag is provided in order to increase the brightness of the nitride semiconductor light emitting device.

The reflecting layer 150 is formed on the AlGaN layer 220 so as to be surrounded by a barrier 300.

The barrier 300 is composed of a first barrier 310 having a larger thickness than the reflecting layer 150 and a second barrier 320 which is surrounded by the first barrier 310 and is covered on the reflecting layer 150. Such a construction prevents a reflecting material such as Ag composing the reflecting layer 150 from being diffused outside, thereby preventing an increase in leakage current. At this time, the first barrier 310 positioned on the AlGaN layer 220 is preferably formed of undoped GaN or a silicon-based insulating material (for example, SiO₂ and SiOₓ) which is strongly adhesive to the AlGaN layer 220, and the second barrier 320 is preferably formed of metal such as Cr/Ni or TiW.

In the present invention as described above, the reflecting material composing the reflecting layer 150 is prevented from being diffused outside through the barrier and thus a leakage current does not increase, which makes it possible to enhance characteristics and reliability of the nitride semiconductor light emitting device.

In the interface between the AlGaN layer 220 and the reflecting layer 150, an adhesive layer (not shown) is preferably positioned to enhance the adherence between the AlGaN layer 220 and the reflecting layer 150. Such an adhesive layer allows the effective carrier density of the p-type nitride semiconductor layer to be increased. Therefore, the adhesive layer is preferably formed of metal which preferentially reacts with components of the compound composing the p-type nitride semiconductor layer except for nitrogen.

Between the AlGaN layer 220 and the reflecting layer 150 or between the adhesive layer (not shown) and the reflecting layer 150 when the adhesive layer is present as in the present embodiment, an ITO electrode (not shown) having relatively high transmittance is further included, so that external emission efficiency can be guaranteed and simultaneously the contact resistance can be significantly improved.

Now, a method of manufacturing the nitride semiconductor light emitting device according to the first embodiment of the invention will be described in detail with reference to FIGS. 5A to 5F as well as FIGS. 3 and 4.

FIGS. 5A to 5F are cross-sectional views for sequentially explaining the method of manufacturing the nitride semiconductor light emitting device according to the first embodiment of the invention.

First, as shown in FIG. 5A, the n-type nitride semiconductor layer 120, the active layer 130, and the p-type nitride semiconductor layer 140 are sequentially formed on the substrate 110. The p-type and n-type nitride semiconductor layers 120 and 140 and the active layer 130 can be formed of a semiconductor material having a composition of AlₓIn_{y}Ga_{(1-x-y)}N (herein, 0≦x≦1, 0≦y≦1, and 0≦x+y≦1) and can be formed by a well-known nitride deposition process such as MOCVD or MBE. The substrate 110 is suitable for growing nitride semiconductor single crystal and can be formed of a heterogeneous substrate such as a sapphire substrate or SiC substrate or a homogeneous substrate such as a nitride substrate.

As shown in FIG. 5B, the heterojunction structure composed of the undoped GaN layer 210 and the AlGaN layer 220 is formed on the p-type nitride semiconductor layer 140.

The undoped GaN layer 210 and the AlGaN layer 220 can be consecutively deposited in a chamber in which the deposition of the nitride layers is performed. Further, in order to guarantee the tunneling effect through the two-dimensional electron gas layer 230, the thickness t1 of the undoped GaN layer 210 is in the range of 10 to 100 Å, and the AlGaN layer 220 is formed to have a thickness of 50 to 250 Å in consideration of a desired Al content. The Al content of the AlGaN layer 220 is preferably limited to 10 to 50% in order to prevent a reduction in crystallinity caused by an excessive Al content.

In addition, the AlGaN layer 220 can be formed of an n-type AlGaN material which is doped with Si as an n-type impurity. Without being limited thereto, however, an undoped AlGaN layer can be used.

Next, an annealing process of the AlGaN layer 220 can be performed in an oxygen (O₂) atmosphere. The present process can be selectively performed, if necessary, in which an amount of oxygen acting as a donor is increased on purpose. As described above, the annealing process is generally adopted in order to enhance crystallinity. Therefore, the annealing process according to the invention can be easily realized by setting an atmosphere gas to oxygen.

As described in FIG. 5C, the first barrier 310 is formed to define a reflecting layer forming region R on the AlGaN layer 220. The first barrier 310 is formed of undoped GaN or a silicon-based insulating material.

When the first barrier 310 is formed by using the undoped GaN, undoped GaN is first grown on the AlGaN layer 220. Then, the grown undoped GaN (not shown) is selectively etched so as to define the reflecting layer forming region R, thereby forming the first barrier 310. At this time, such an etching process can be performed through both wet etching and dry etching. Preferably, the grown undoped GaN (not shown) has a larger thickness than the reflecting layer which will be described below.

When the first barrier 310 is formed by using the silicon-based insulating material, a silicon-based insulating material (for example, SiO₂ and SiNₓ; not shown) is formed to have a predetermined thickness on the AlGaN layer 220. Then, the silicon-based insulating material is selectively etched so as to define the reflecting layer forming region R, thereby forming the first barrier 310. At this time, such an etching process can be performed through both wet etching and dry etching, as described above. Preferably, the silicon-based insulating material (not shown) has a larger thickness than the reflecting layer which will be described below.

As described in FIG. 5D, the reflecting layer 150 composed of a reflecting material such as Ag is formed in the reflecting layer forming region R on the AlGaN layer 220 defined by the first barrier 310.

Although not shown, an adhesive layer (not shown) can be additionally formed in order to enhance the adherence between the AlGaN layer 220 and the reflecting layer 150, before the reflecting layer 150 is formed.

When the adhesive layer is formed, an ITO electrode (not shown) having relatively high transmittance is additionally formed between the adhesive layer (not shown) and the reflecting layer 150, so that external emission efficiency is guaranteed and simultaneously the contact resistance is significantly improved.

As described in FIG. 5E, the second barrier 320 is formed on the side wall of the first barrier 310 and the upper surface of the reflecting layer 150. The barrier 300 composed of the first and second barriers 310 and 320 completely blocks the reflecting layer from the outside so as to prevent a reflecting material composing the reflecting layer 150 from being diffused outside. At this time, the second barrier 320 is preferably formed of metal such as Cr/Ni or TiW.

As described in FIG. 5F, the p-type electrode 170 is formed on the second barrier 320 formed of metal.

Further, the sapphire substrate 110 is removed through an LLO process, and the n-type electrode 180 is then formed on the n-type nitride semiconductor layer 120 where the sapphire substrate 110 is removed, thereby forming a vertically-structured nitride semiconductor light emitting device (refer to FIG. 3).

In the above-described first embodiment, the barrier which is formed on the AlGaN layer so as to surround the reflecting layer has been formed in the above-described method, in which the first barrier defining the reflecting layer forming region is patterned, the reflecting layer is formed, and the second barrier is formed to cover the reflecting layer. However, in the present modified embodiment, the reflecting layer can be first formed by using photoreaction polymer such as photoresist, and the barrier can be then formed.

Although not shown more specifically, the reflecting layer is first formed on the AlGaN layer, a photoresist pattern defining the first barrier forming region is formed on the reflecting layer, and the reflecting layer is etched with the pattern set to an etching mask, thereby exposing the AlGaN layer corresponding to the first barrier forming region.

Then, the first barrier having a larger height than the reflecting layer is patterned on the exposed AlGaN layer, and the second barrier is formed on the first barrier and the reflecting layer. At this time, the first barrier can be formed by growing the exposed undoped GaN layer by a predetermined thickness.

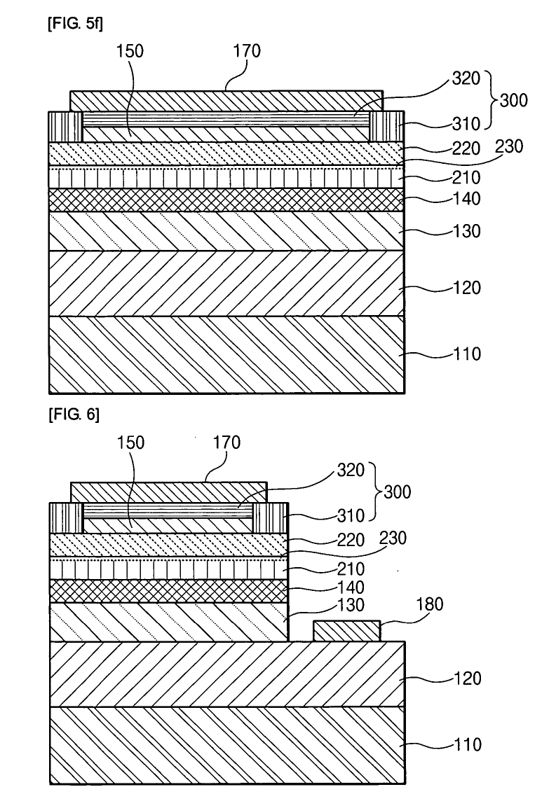

Referring to FIG. 6, a second embodiment of the invention will be described. The descriptions of the same components as those of the first embodiment will be omitted, and only different components will be described in detail.

FIG. 6 is a cross-sectional view illustrating the structure of a nitride semiconductor light emitting device according to the second embodiment.

As described in FIG. 6, the construction of the nitride semiconductor light emitting device according to the second embodiment is almost the same as that of the nitride semiconductor light emitting device according to the first embodiment. However, the n-type electrode 180 is not formed on the rear surface of the n-type nitride semiconductor layer 120 on which the active layer is formed, but is formed on a surface which is exposed by removing portions of the active layer 130, the p-type nitride semiconductor layer 140, the undoped GaN layer 210, and the AlGaN layer 220, that is, on the n-type nitride semiconductor layer 120 on which the active layer is formed. On the rear surface of the n-type nitride semiconductor layer 120, the sapphire substrate 110 is formed to come in contact with the n-type nitride semiconductor layer.

In other words, the first embodiment exemplifies a vertically structured light emitting diode, and the second embodiment exemplifies a flip chip light emitting diode. The second embodiment can obtain the same operation and effect as the first embodiment.

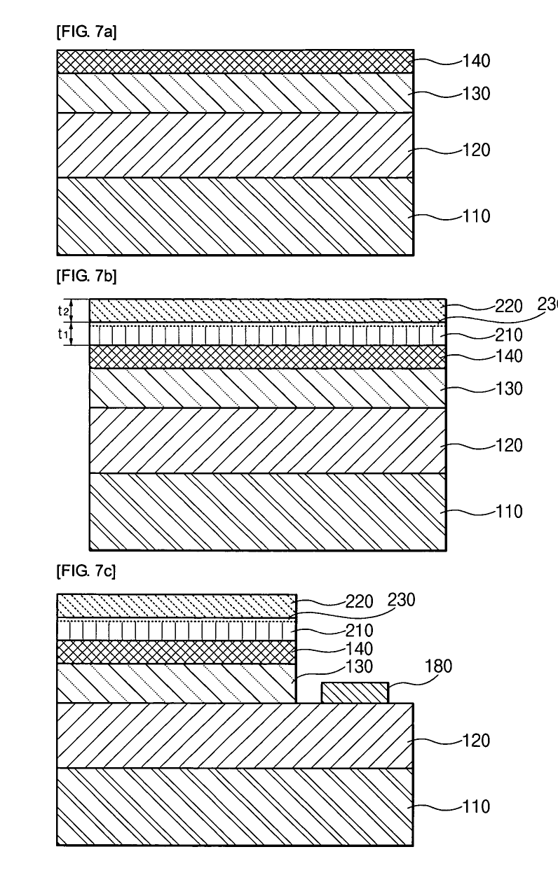

Now, a method of manufacturing the nitride semiconductor light emitting device according to the second embodiment of the invention will be described in detail with reference to FIGS. 7A to 7C as well as FIGS. 5A to 5F and 6.

FIGS. 7A to 7C are cross-sectional views for sequentially showing the method of manufacturing the nitride semiconductor light emitting device according to the second embodiment of the invention.

First, as described in FIGS. 7A and 7B, the n-type nitride semiconductor layer 120, the active layer 130, and the p-type nitride semiconductor layer 140 are sequentially formed on the substrate 110, and the heterojunction structure (2 DEG) composed of the undoped GaN layer 210 and the AlGaN layer 220 is formed on the p-type nitride semiconductor layer 140, similar to the first embodiment.

As shown in FIG. 7C, a portion of the heterojunction structure composed of the undoped GaN layer 210 and the AlGaN layer 220 and portions of the p-type nitride semiconductor layer 140 and the active layer 130 are removed by mesa etching so that a portion of the n-type nitride semiconductor layer 120 is exposed, and the n-type electrode 180 is formed on the exposed upper surface of the n-type nitride semiconductor layer 120. Through such a construction, a nitride semiconductor light emitting device having a flip chip structure is formed.

The Fab processes after forming the n-type electrode 180 are performed the same as those of the first embodiment and the modified embodiment. In the second embodiment, however, the n-type electrode has been already formed as shown in FIG. 7C. Therefore, the LLO process of removing the sapphire substrate 110 so as to form the n-type electrode is omitted, and thus the sapphire substrate 110 remains as it is (refer to FIG. 6).

In the present invention as described above, the GaN/AlGaN heterojunction structure which is undoped on the upper portion of the p-type nitride semiconductor layer is adopted. Through the tunneling effect of the two-dimensional electron gas layer thereof, the resistance of the p-type nitride semiconductor layer is minimized, so that an operational voltage of the nitride semiconductor light emitting device can be reduced and a current-spreading effect can be enhanced.

Further, since high carrier mobility and carrier density can be guaranteed by the two-dimensional electron gas layer, excellent current injection efficiency is realized.

Furthermore, the reflecting material of the reflecting layer which is provided for implementing a high-brightness nitride semiconductor light emitting device is prevented from being diffused outside, thereby minimizing a leakage current.

Accordingly, the present invention has such an effect that the characteristics and reliability of the nitride semiconductor light emitting device can be enhanced and simultaneously the yield can be enhanced.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride semiconductor light emitting device comprising:
an n-type electrode;
an n-type nitride semiconductor layer that is formed to come in contact with the n-type electrode;
an active layer that is formed on the n-type nitride semiconductor layer;
a p-type nitride semiconductor layer that is formed on the active layer;
an undoped GaN layer that is formed on the p-type nitride semiconductor layer;
an AlGaN layer that is formed on the undoped GaN layer so as to provide a two-dimensional electron gas layer to the interface with the undoped GaN layer;
a reflecting layer that is formed on the AlGaN layer;
a barrier that is formed so as to surround the reflecting layer; and
a p-type electrode that is formed on the barrier.

2. The nitride semiconductor light emitting device according to claim 1,
wherein the barrier is formed on the AlGaN layer, and is composed of a first barrier which has a larger thickness than the reflecting layer and a second barrier which is formed on the reflecting layer while coming in contact with the side wall of the first barrier.

3. The nitride semiconductor light emitting device according to claim 2,
wherein the first barrier is formed of any one film selected from a group composed of undoped GaN, SiO₂, and SiNₓ.

4. The nitride semiconductor light emitting device according to claim 2 or 3,
wherein the second barrier is formed of Cr/Ni or TiW.

5. The nitride semiconductor light emitting device according to claim 1 further including
an ITO electrode that is provided between the AlGaN layer and the reflecting layer.

6. The nitride semiconductor light emitting device according to claim 1 further including
an adhesive layer that is provided in the interface between the AlGaN layer and the reflecting layer.

7. The nitride semiconductor light emitting device according to claim 1,
wherein the undoped GaN layer has a thickness of 50 to 500 Å.

8. The nitride semiconductor light emitting device according to claim 1,
wherein the Al content of the AlGaN layer is in the range of 10 to 50%.

9. The nitride semiconductor light emitting device according to claim 1,
wherein the AlGaN layer has a thickness of 50 to 500 Å.

10. The nitride semiconductor light emitting device according to claim 1,
wherein the AlGaN layer is an undoped AlGaN layer.

11. The nitride semiconductor light emitting device according to claim 1,
wherein the AlGaN layer is an AlGaN layer which is doped with an n-type impurity.

12. The nitride semiconductor light emitting device according to claim 1,
wherein the AlGaN layer contains silicon or oxygen as an impurity.

13. The nitride semiconductor light emitting device according to claim 1,
wherein the n-type electrode is formed on the rear surface of the n-type nitride semiconductor layer on which the active layer is formed, and is a vertically-structured light emitting device.

14. The nitride semiconductor light emitting device according to claim 1,
wherein the device is a flip chip light emitting device, in which the n-type electrode is formed on the n-type nitride semiconductor layer so as to be spaced at a predetermined distance with the active layer, including the active layer and the substrate which is formed on the rear surface of the n-type nitride semiconductor layer on which the n-type electrode is formed.

15. A method of manufacturing a nitride semiconductor light emitting device comprising:
forming an n-type nitride semiconductor layer on a substrate;
forming an active layer on the n-type nitride semiconductor layer;
forming a p-type nitride semiconductor layer on the active layer;
forming an undoped GaN layer on the p-type nitride semiconductor layer;
forming an AlGaN layer on the undoped GaN layer so that a two-dimensional electron gas layer is formed in the junction interface with the undoped GaN layer;
forming a reflecting layer and a barrier on the AlGaN layer, the barrier surrounding the reflecting layer;
forming a p-type electrode on the barrier; and
forming an n-type electrode which comes in contact with the n-type nitride semiconductor layer.

16. The method of manufacturing a nitride semiconductor light emitting device according to claim 15,
wherein forming the reflecting layer and the barrier on the AlGaN layer, the barrier surrounding the reflecting layer, further includes:
patterning a first barrier defining the reflecting layer forming region on the AlGaN layer;
forming the reflecting layer in the reflecting layer forming region on the AlGaN layer so that the reflecting layer has a smaller height than the first barrier; and
forming a second barrier on the first barrier and the reflecting layer.

17. The method of manufacturing a nitride semiconductor light emitting device according to claim 16,
wherein patterning the first barrier includes:
growing the undoped GaN layer on the AlGaN layer so that the undoped GaN layer has a predetermined thickness; and
selectively etching the grown undoped GaN layer so that the reflecting layer forming region is defined.

18. The method of manufacturing a nitride semiconductor light emitting device according to claim 16,
wherein patterning the first barrier includes:
forming a silicon-based insulating film on the AlGaN layer so that the insulating film has a predetermined thickness; and
selectively etching the silicon-based insulating film so that the reflecting layer forming region is formed.

19. The method of manufacturing a nitride semiconductor light emitting device according to claim 15,
wherein forming the reflecting layer and the barrier on the AlGaN layer, the barrier surrounding the reflecting layer, includes:
forming the reflecting layer on the AlGaN layer;
removing a predetermined region of the end portion of the reflecting layer;
patterning a first barrier on the AlGaN layer in which the reflecting layer is removed, the first barrier having a larger height than the reflecting layer; and
forming a second barrier on the first barrier and the reflecting layer.

20. The method of manufacturing a nitride semiconductor light emitting device according to claim 19,
wherein, on the AlGaN layer in which the reflecting layer is removed, the first barrier is formed by growing the undoped GaN layer so that the undoped GaN layer has a predetermined thickness.

21. The method of manufacturing a nitride semiconductor light emitting device according to claim 15 further including
forming an adhesive layer on the interface between the AlGaN layer and the reflecting layer.

22. The method of manufacturing a nitride semiconductor light emitting device according to claim 15 further including
annealing the AlGaN layer in an oxygen atmosphere after forming the AlGaN layer.

23. The method of manufacturing a nitride semiconductor light emitting device according to claim 15 further including
forming an ITO electrode between the AlGaN layer and the reflecting layer before forming the reflecting layer.

24. The method of manufacturing a nitride semiconductor light emitting device according to claim 15,
wherein forming the n-type electrode which comes in contact with the n-type nitride semiconductor layer includes:
mesa-etching portions of the active layer and the p-type nitride semiconductor layer so as to expose a portion of the n-type nitride semiconductor layer before forming the undoped GaN layer on the p-type nitride semiconductor layer; and
forming the n-type electrode on the exposed n-type nitride semiconductor layer.

25. The method of manufacturing a nitride semiconductor light emitting device according to claim 15,
wherein forming the n-type electrode which comes in contact with the n-type nitride semiconductor layer includes:
removing the substrate which comes in contact with the n-type nitride semiconductor layer; and
forming the n-type electrode on the n-type nitride semiconductor layer in which the substrate is removed.
